(19) United States
(12) Patent Application Publication
(10) Pub. No.: US 2009/0104462 A1
(43) Pub. Date: Apr. 23, 2009

(54) X-RAY MULTILAYER FILMS AND SMOOTHING LAYERS FOR X-RAY OPTICS HAVING IMPROVED STRESS AND ROUGHNESS PROPERTIES AND METHOD OF MAKING SAME

(75) Inventor: David L. Windt, New York, NY (US)

Correspondence Address: PRYOR CASHMAN, LLP, 410 PARK AVENUE, NEW YORK, NY, 10022, US

(73) Assignee: REFLECTIVE X-RAY OPTICS LLC, New York, NY (US)

(21) Appl. No.: 12/189,366

(22) Filed: Aug. 11, 2008

Related U.S. Application Data
(60) Provisional application No. 60/965,186, filed on Aug. 16, 2007.

(51) Int. Cl. B32B 15/04; C23C 14/34

(52) U.S. Cl. 428/457; 204/192.15

(57) ABSTRACT

X-ray reflective multilayer films with greatly reduced surface roughness and film stress, and smoothing layers for reducing surface roughness of X-ray reflective film substrates, are produced by reactive sputter deposition using a sputter gas having nitrogen in combination with at least one inert gas. The nitrogen is incorporated into the film in a non-stoichiometric manner. Preferably, a gas fraction of the nitrogen is between approximately 5% and approximately 25%. The inert gas is preferably argon. In one embodiment, the materials to be reactively sputtered may include tungsten and boron carbide in alternating layers of the multilayer film. Alternatively, nickel and boron carbide or cobalt and carbon may be used in alternating layers of the multilayer film. Boron carbide may serve as the material for the smoothing layer.

### RELATED APPLICATIONS

Domestic priority is claimed from U.S. Provisional Patent Application No. 60/965,186 entitled “X-Ray Multilayer Films and Smoothing Layers for X-Ray Optics Having Improved Stress and Roughness Properties” filed Aug. 16, 2007, the teachings of which are entirely incorporated by reference herein.

### STATEMENT OF FEDERALLY SPONSORED RESEARCH OR DEVELOPMENT

This research was supported by National Aeronautics and Space Administration grants NNG06WC15G and NNG06HA04G.

### BACKGROUND OF THE INVENTION

1. Field of the Invention

The invention relates to a method for manufacturing X-ray multilayer films and substrate smoothing layers by reactive magnetron sputter deposition.

2. Description of Related Art

Nanometer-scale multilayer thin films are now widely used in a variety of scientific and industrial applications as reflective mirror coatings operating in the EUV, soft X-ray, and hard X-ray bands. The performance of these coatings depends crucially on the smoothness of the interfaces between each layer comprising the stack, as interfacial roughness will scatter X-rays into non-specular directions, thereby reducing the net specular reflectance. The surface roughness of the underlying substrate is also crucially important, since the substrate roughness can be replicated at each interface in the multilayer stack, also leading to increased scattering and reduced reflectance. Film stress is an additional critical parameter that must be minimized in order to avoid coating adhesion failure, substrate distortion, and other problems.

An X-ray multilayer coating or film includes a stack of nanometer-scale thin layers of optically dissimilar materials, arranged on a substrate such that the X-ray reflections occurring at each interface add coherently, in phase, giving rise to high reflectance over a relatively narrow range of incidence angles and photon energies. By adjusting the thickness of a pair of layers during fabrication, the response of the film can be tuned precisely and arbitrarily in energy as desired.

X-ray multilayer films can be produced using a variety of deposition techniques. Magnetron sputtering is one deposition technique that is widely used for the production of X-ray multilayers, for a variety of reasons. In magnetron sputtering, solid targets of the materials to be deposited are bombarded by energetic gas atoms and ions generated in a magnetically-confined plasma. The bombardment causes target atoms to be ejected from the target; these atoms then travel to the substrate surface where they condense to form the growing film. By careful control of the plasma energy and spatial distribution, sub-Å layer thickness control can be achieved, as is necessary for good multilayer performance.

To produce a multilayer film by magnetron sputtering, two targets are used. In one common method, the substrate rotates under computer control past the two targets (i.e., magnetron cathodes), building up the multilayer one layer per pass. The coating thickness uniformity across the substrate surface is controlled also with sub-Å accuracy by precise control of both the substrate velocity, and the distance and orientation of the substrate relative to the targets.

Sputter deposition (magnetron or otherwise) must be performed in a vacuum: the air is pumped out of the vacuum chamber, and when a sufficiently low vacuum pressure is reached, the sputter gas is introduced at a controlled flow rate and/or a controlled pressure. The sputter gas is ionized to create the plasma described above that is used to liberate target atoms from the solid target.

The sputtering process can be either ‘reactive’ or ‘non-reactive’. Non-reactive sputtering uses an inert gas, typically argon (Ar), but sometimes (though rarely) helium, neon, krypton or xenon. Reactive sputtering involves the introduction of one or more additional non-inert (i.e., reactive) gases, like oxygen, nitrogen, etc., in order to affect the chemical composition of the film. For example, reactive sputtering with oxygen can be used to produce metal-oxide coatings, while reactive sputtering with nitrogen can be used to produce metal-nitride coatings. Reactive sputtering is thus most commonly used to control chemical composition of the coating, i.e., to produce nitrides, oxides, etc.

Many deposition and film growth techniques have been investigated with the aim of reducing roughness and film stress in X-ray multilayers. However a single deposition technique that reduces both roughness and stress simultaneously has proven elusive; these two characteristics are often inversely correlated with each other, particularly in the case of commonly used X-ray multilayer structures such as Mo/Si, W/Si, W/B₄C, etc., typically grown by magnetron sputtering. The inverse correlation between film stress and surface roughness occurring commonly in sputtered films can be understood as a manifestation of the microstructure of the individual layers. In the context of the structure-zone model described by Thornton (J. Vac. Sci. Technol. 11, 666-670 (1974)) and revised by Messier et al. (J. Vac. Sci. Technol. A2, 500-503 (1984)), the smoothest sputtered films are characterized by a zone T-type microstructure comprising tightly packed columnar grains, an over-dense structure with large compressive stresses. As the deposition conditions change (for example, by increasing the sputter gas pressure) so as to produce films having lower (compressive) stresses, the film tends towards the zone 1-type microstructure characterized by porous columnar grains with large surface roughness, ultimately producing tensile stresses due to attractive forces between the columnar grains.

As mentioned briefly above, one of the key factors in X-ray reflective multilayer performance for a given pair of materials is the quality of the interfaces. Any roughness or chemical diffusion at the interfaces will reduce the X-ray reflectance. As a consequence, any deposition techniques that can improve the quality of the interfaces, without degrading the optical properties of the layers, can be beneficial. Similarly, good multilayer performance also requires that the underlying substrate on which the multilayer coating is deposited be as smooth as possible. The multilayer coating will, in general, replicate the surface topography of the substrate. Any high-frequency roughness present in the substrate can propagate through each interface in the multilayer stack, thereby degrading the X-ray performance of the coating. (“X-ray scattering” is the mechanism by which interfacial roughness degrades X-ray reflectance. That is, when an X-ray encounters a rough surface, the X-ray can be reflected or ‘scattered’ into a direction away from the ‘specular’ direction, thereby reducing the ‘specular reflectance’ and increasing the ‘non-specular’ or ‘diffuse’ scattered light intensity.) Consequently, the best substrates for X-ray mirrors must be very smooth. The requisite smoothness is conventionally achieved by precision polishing techniques in materials such as glass, silicon, etc.

A subtle but nevertheless crucial consideration relating to surface roughness for X-ray mirrors, or interfacial roughness in X-ray multilayer films, is that the roughness must be controlled over the correct range of spatial frequencies: the relevant range of spatial frequencies scales with the wavelength of light (i.e., X-rays). Thus, low-frequency roughness, which is typically measured with a contact profilometer or by visible light interference techniques, has little impact on X-ray performance. In contrast, very high-frequency roughness, as measured using an Atomic Force Microscope (AFM) at spatial wavelengths of about 1 micron and smaller, has a direct impact on X-ray performance.

Another important property of X-ray multilayer films is the film stress. The stress obtained in films deposited by magnetron sputtering will depend on the specific material being deposited, and on a large number of deposition parameters such as sputter gas pressure, background pressure, target-to-substrate distance, etc. In multilayer films, the net film stress will also depend on the thicknesses of the individual layers and on the nature of the interfaces. In any case, film stress can be either positive (tensile) or negative (compressive), which means the relaxed film, i.e., if it were somehow removed from the substrate, would either contract or expand. Either way, high stress in thin films is deleterious: it can cause the film to peel, or to fail in other ways. It is often difficult or impossible to control (i.e., reduce) film stress without degrading the X-ray performance of the film. As a result, there is a long-felt need to control stress in X-ray reflective films without degrading other measures of performance.

Ultra-short period, narrow-band W/B₄C multilayers have already been shown to work reasonably well at wavelengths in the 1.5-2.5 nm range near normal incidence, yet the performance of these films could be improved further if the interfacial roughness in these structures could be reduced. The inventor has also previously produced prototype depth-graded WB₄C multilayers, however the large stresses in these coatings have precluded their use thus far, as films deposited onto figured thin glass substrates (as would be used in the construction of astronomical multilayer X-ray telescopes, for example) have suffered catastrophic stress-driven adhesion failures.

### SUMMARY OF THE INVENTION

The above and other needs are fulfilled by the invention, which is a method for producing X-ray reflective multilayers films and associated smoothing layers, and the films themselves, having extremely low film stress and surface roughness.

One aspect of the invention includes an X-ray reflective multilayer film produced by reactive sputter deposition using a sputter gas including nitrogen in combination with at least one inert gas. The nitrogen is incorporated into the film in a non-stoichiometric manner. Preferably, a gas fraction of the nitrogen (to be defined below) is between approximately 5% and approximately 25%. The inert gas is preferably argon. In one embodiment, the materials to be reactively sputtered may include tungsten and boron carbide in alternating layers of the multilayer film. In another embodiment, the materials to be reactively sputtered may include nickel and boron carbide in alternating layers of the multilayer film. In a third embodiment, the materials to be reactively sputtered may include cobalt and carbon in alternating layers of the multilayer film.

Another aspect of the invention includes an X-ray optical element substrate smoothing layer. The smoothing layer is produced by reactive sputter deposition using a sputter gas including nitrogen in combination with at least one inert gas. Deposition of the smoothing layer onto the substrate reduces a surface roughness of the substrate. A gas fraction of the nitrogen is between approximately 5% and approximately 25%, and the inert gas preferably includes argon. The material to be reactively sputtered into the smoothing layers is boron carbide.

Yet another aspect of the invention is a method of creating extremely smooth and low-stress X-ray multilayer reflective films. The steps of the inventive method include providing a film substrate, and sputtering at least one material onto the substrate using a sputter gas mixture of nitrogen and at least one inert gas. A gas fraction of the nitrogen is preferably between approximately 5% and approximately 25%, and the inert gas preferably includes argon. The sputtering step preferably further includes the steps of depositing two different materials in alternating layers to form an X-ray multilayer film. The two different materials of the depositing step are preferably at least one of the following pairs: i) tungsten and boron carbide; ii) nickel and boron carbide; or iii) cobalt and carbon.

A fourth aspect of the invention is a method of creating an X-ray optical element substrate smoothing layer, including the steps of providing a film substrate, and reducing the surface roughness of the substrate by sputtering a material onto the substrate using a sputter gas mixture of nitrogen and at least one inert gas. This method may further include the step of depositing at least one additional layer of material atop the smoothing layer to form an X-ray reflective film. The sputter material includes boron carbide.

The inventor has determined that X-ray multilayer structures grown by reactive DC magnetron sputtering using a nitrogen-argon gas mixture exhibit significantly reduced stress and roughness properties, thereby leading to better performance. In particular, we have studied both periodic and depth-graded W/B₄C and Co/C multilayers. We have also studied the properties of single-layer W and B₄C films, in order to understand specifically how the stress, roughness, chemical composition and microstructure in these materials depends on the sputter gas composition. Reactive sputtering with nitrogen will result in the incorporation of nitrogen in the films, which may degrade multilayer optical performance in the EUV where nitrogen is strongly absorbing. However, the incorporation of nitrogen has little, if any, effect on the optical constants of these materials at shorter wavelengths in the soft and hard X-ray bands. Thus, nitrogen incorporation is not problematic for X-ray multilayers. It is equally unproblematic for nanometer-scale smoothing layers, since these are solely used to flatten the topography of a film substrate prior to the deposition of reflective materials.

The W/B₄C and Co/C multilayer systems selected for study here have importance for both normal-incidence applications in the soft X-ray band using periodic structures, and for grazing-incidence applications in the hard X-ray for which depth-graded structures are required to achieve broad-energy response.

### BRIEF DESCRIPTION OF THE DRAWINGS

FIG. 1 is a series of graphs showing (a) concentration of nitrogen from XPS measurements (b) deposition rate, (c) surface roughness, and (d) film stress as a function of N₂ Gas Fraction for W (circles) and B₄C (squares) films.

FIG. 2A are two atomic force microscope images illustrating the improved surface roughness characteristics of tungsten layers deposited in accordance with the invention.

FIG. 2B is a graph showing power-spectral-density curves for 100 nm-thick W and WNₓ films, as labeled.

FIG. 3 is a graph showing X-ray diffraction measurements for 100-nm-thick W (solid) and WNₓ (dotted) films, as labeled.

FIG. 4 is a pair of graphs showing power-spectral-density curves determined from atomic force microscopy, for B₄CNₓ films as a function of thickness, as deposited onto (a) Si (100) wafers and (b) 0.2-mm-thick Corning #0211 glass sheet.

FIG. 5 is a graph showing X-ray reflectance measurements for periodic W/B₄C multilayers having 40 periods, with d=11.25 Å, deposited non-reactively using Ar gas, and reactively using an Ar/N₂ gas mixture, as labeled.

FIG. 6 is a graph showing X-ray reflectance measurements for depth-graded W/B₄C multilayers containing 200 bilayers, with dₘᵢₙ=25 Å and dₘₐₓ=450 Å, deposited non-reactively using Ar gas, and reactively using an Ar/N₂ gas mixture, as labeled. The calculated response based on this multilayer design is also shown.

FIG. 7 is a graph showing stress-versus-temperature measurements for depth-graded W/B₄C multilayers containing 200 bilayers, with dₘᵢₙ=25 Å and dₘₐₓ=450 Å, deposited non-reactively using Ar gas, and reactively using an Ar/N₂ gas mixture, as labeled.

FIG. 8 is a table showing Ar and N₂ flow rates used for samples prepared in the Vactec deposition system in accordance with the invention.

FIG. 9 is a table showing Ar and N₂ flow rates used for samples prepared in the S-Gun deposition system in accordance with the invention.

FIGS. 10A-B are top and side elevation schematics of a sputter deposition system used in accordance with the invention.

### DETAILED DESCRIPTION OF THE INVENTION AND DRAWINGS

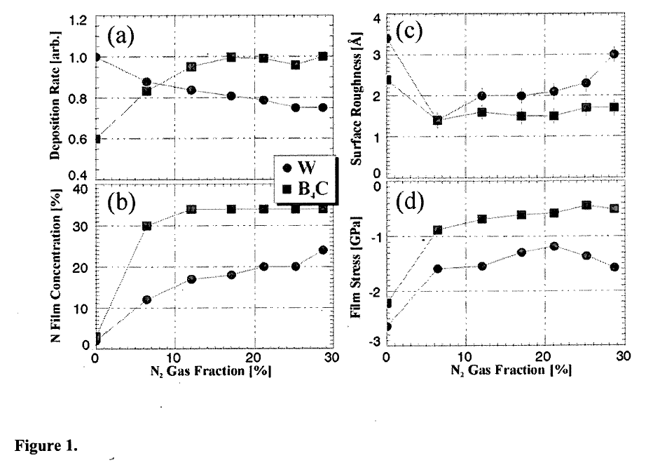

Description of the invention will now be given with reference to FIGS. 1-10. It should be understood that these figures are exemplary in nature and in no way serve to limit the scope of the invention, which is defined by the claims appearing hereinbelow.

Film Deposition

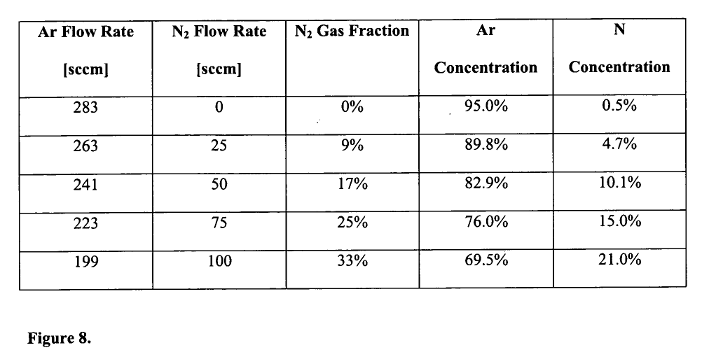

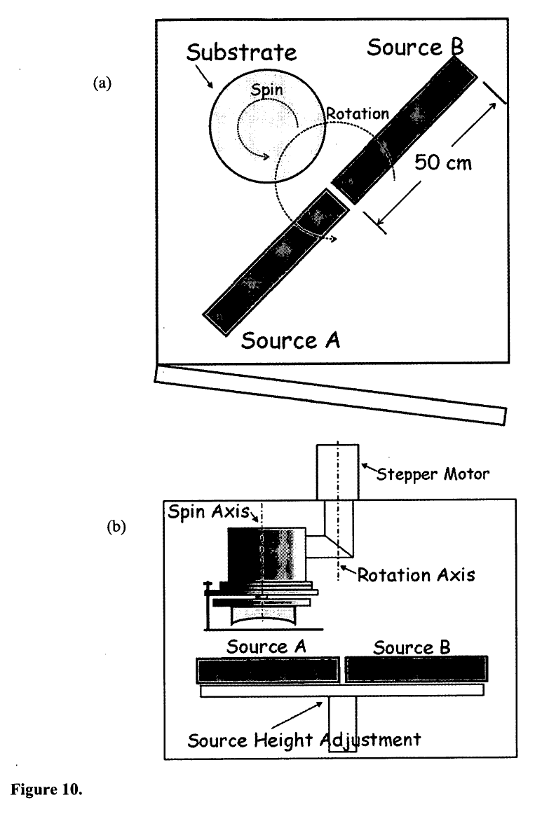

All films studied here were deposited by DC magnetron sputtering in one of two separate deposition systems. The first system has been described in Windt and Waskiewicz “Multilayer facilities for EUV lithography”, J. Vac. Sci. Technol. B., 12, 2826-3832 (1994), the teachings of which are incorporated by reference herein. This “Vactec” system, schematically illustrated in top and side view in FIGS. 10A-B, utilizes 50.8 cm×8.9 cm rectangular planar magnetron cathodes. The cathodes are arranged along the diagonal of the square vacuum chamber and sputter up, while the substrate faces down as it rotates past each cathode. The computer-controlled substrate rotational velocity is used to control individual layer thicknesses (i.e, faster rotation produces thinner layers.) The substrate also spins at approximately 230 rpm as it rotates, in order to improve coating thickness uniformity. The cathodes are powered by regulated DC power supplies (Advanced Energy model MDX 5K) operated in constant-power mode. The vacuum chamber is cryo-pumped and can reach an ultimate base pressure of less than 3.0×10⁻⁸ Torr. The films discussed below were deposited after pumping for approximately 24 hours, at which time the chamber background pressure was typically in the range 1-2×10⁻⁷ Torr. The working gas is introduced into the vacuum chamber during sputtering using mass flow controllers (MKS model 2259C) that are operated in a closed-loop feedback configuration set to operate at a constant total gas pressure as measured by a high-precision capacitance manometer (MKS model 390HA). All films deposited in the Vactec system were grown using a total sputter gas pressure of 1.6 mTorr, with a target-to-substrate distance of 10 cm. For non-reactive sputtering, argon of 99.998% purity was used with a resultant flow rate of approximately 280 sccm. For reactive sputtering with nitrogen, N₂ gas of 99.998% purity was used and the N₂ flow rate was set manually; the Ar flow rate was automatically reduced accordingly in order to maintain a constant total gas pressure. FIG. 8 lists the Ar and N₂ flow rates, along with the effective “N₂ Gas Fraction”, which we define as the N₂ flow rate divided by the total Ar+N₂ flow rates. Also listed are Ar and N₂ gas concentrations in the vacuum chamber as determined using a residual gas analyzer (Stanford Research Systems model RGA 200.) All films grown in the Vactec system were made with the W cathode operating at 100 W and the B₄C cathode at 500 W.

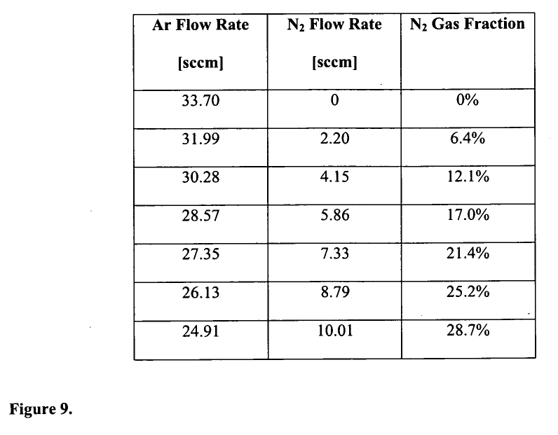

The second deposition system used to produce some of the films studied here utilizes 4.5 cm diameter circular “S-Gun” magnetron cathodes, which comprise a concentric anode-cathode configuration (as described in Dalla Torre, Gilmer, Windt et al., “Microstructure of thin tantalum films sputtered onto inclined substrates: experiments and atomistic simulations”, J. App. Phys., 94, 263-271 (2003), the teachings of which are incorporated by reference herein). The S-Gun system is similar to the Vactec system just described, in that the cathodes sputter up and the substrate spins as it rotates over the cathodes; the cathodes are again operated in constant-power mode using precision power supplies (Advanced Energy model MDX 500), and gas flow is controlled at constant total gas pressure using a closed-loop feedback configuration employing mass flow controllers and a capacitance manometer (the same model MKS items noted above.) The S-Gun system is pumped using both a turbo- and a cryo-pump, and all samples were deposited after approximately 24 hours pumpdown, thereby reaching a background pressure in the range 2-3×10⁻⁷ Torr. The S-Gun films were deposited at a total gas pressure of 2.0 mTorr, with an 8 cm target-to-substrate distance. (Thus the pressure-distance product is the same in both systems: the pressure-distance product is, in fact, the parameter that largely drives the momentum transferred to adatoms on the surface of the growing film from energetic ions and gas atoms; momentum transfer has a large effect on the resultant microstructure.) FIG. 9 lists the Ar and N₂ flow rates, and the N₂ Gas Fraction (as defined above) as well, for the S-Gun system. The S-gun system is not fitted with an RGA, so no gas concentration measurements were available. For the work described here, the W cathode was operated at 40 W power, while the B4C cathode at 60 W.

X-Ray Analysis

Grazing incidence X-ray reflectance (XRR) measurements were made in the θ-2θ geometry using an X-ray diffractometer comprising a sealed-tube Cu anode operating at 1.3 kW, and a Ge crystal monochromator tuned to the Cu K-α line (8 keV). The sample and detector are positioned using a 4-circle Huber goniometer. Fits to the measured XRR data were used to determine film thicknesses in the case of single-layer films, and the multilayer period d in the case of periodic multilayer films. X-ray diffraction (XRD) measurements were made using the same system for selected samples as described below, also in the θ-2θ geometry.

Atomic Force Microscopy

The surface roughness of selected samples was measured using an atomic force microscope (Veeco model Nanoscope IIIa controller, with Dimension 3100 microscope and Dimension AFM Scan Head). The AFM measurements were made in ‘tapping-mode’ using a Si probe tip (Veeco model TESP7), with 512 points acquired over a 2 μm scan length, corresponding to spatial frequencies in the range 0.5-128 μm⁻¹. The radially-averaged Power-Spectral-Density (PSD) function was computed from the 2D AFM data using the TOPO software package created by the inventor herein.

Film Stress

Film stress was measured using a wafer curvature system (Toho Technologies model Flexus 2320S). Selected samples were deposited onto 75 mm Si (100) wafers of nominal 0.4 mm thickness, and the wafer curvature was measured before and after film deposition. The total film thickness as determined by XRR was used to compute film stress, following the standard formalism based on the Stoney equation. In addition, stress-versus-temperature measurements, from room-temperature (25° C.) to 300° C., were made on selected multilayer samples using the same instrument.

X-Ray Photoelectron Spectroscopy

X-ray Photoelectron Spectroscopy (XPS) measurements were made on selected W and B₄C films in order to determine the concentrations of incorporated nitrogen as a function of N₂ Gas Fraction. The XPS measurements were made by Evans Analytical Group (Hightstown, NT), with a Phi 5701 LSci system using Al Kα X-rays (1.4866 keV). Depth-profiling was achieved via Ar ion sputtering.

Results

Single-Layer Films of Wand B₄C

Single-layer films of W and B₄C were first deposited in the S-Gun system described above onto 75-mm diameter Si (100) wafers, at each of the N₂ Gas Fraction values listed in FIG. 9. A total of seven W and seven B₄C films were thus deposited. Apart from the systematic variation in N₂ flow rate, from 0 to 10 sccm, all other deposition conditions were held constant, as per the general description provided in the previous section. Film thicknesses were determined using XRR; the film thicknesses thus determined for the W and B₄C films deposited using pure Ar gas were 24.1 nm and 32.4 nm, respectively, and the thicknesses measured for the remaining films (i.e., deposited reactively) monotonically decreased, in the case of W, and monotonically increased, in the case of B₄C. Film thicknesses were used to compute the relative deposition rate variations with N₂ Gas Fraction, which are shown in FIG. 1a. A large increase in B₄C deposition rate with N₂ Gas Fraction was observed, which is in fact highly advantageous given the very low intrinsic sputtering rate for pure B₄C that is generally a rate-limiting factor in the fabrication of B₄C-based multilayers. While the W deposition rate decreases with N₂ Gas Fraction, the lower W rates are not problematic given the relatively high intrinsic W sputter rate, and the greater heat capacity of the W target which affords relatively high cathode powers if necessary.

Also shown in FIG. 1 are the average nitrogen concentrations determined by XPS (FIG. 1b), the rms surface roughnesses determined from AFM measurements (FIG. 1c), and the film stresses determined by wafer curvature (FIG. 1d). From the XPS data it is clear that the N concentration increases steadily with N₂ Gas Fraction in the case of the W films, reaching a maximum value of 25%; the W films are thus non-stoichiometric nitrides, in general, which we designate henceforth as WNₓ. In contrast, the N concentration saturates at 34% once the N₂ Gas Fraction has reached a value of 12% in the case of the B₄C films. XPS results also indicate that the B₄C concentration ratio is −4:1 for all films, so that the films comprise stoichiometric B₄C regardless of the amount of N also included. For simplicity, we henceforth designate these films as B₄CNₓ.

As can be seen from the rms surface roughness values shown in FIG. 1c, there is a sharp and significant reduction in surface roughness in both the WNₓ and B₄CNₓ films relative to the pure W and B₄C films. There is also a corresponding large decrease in compressive stresses. In particular, the B₄C film has a stress of ˜2.2 GPa, but the B₄CNₓ films all have stresses below −1 GPa; similarly the W film has a stress of −2.6 GPa while the WNₓ films have stresses below −1.5 GPa.

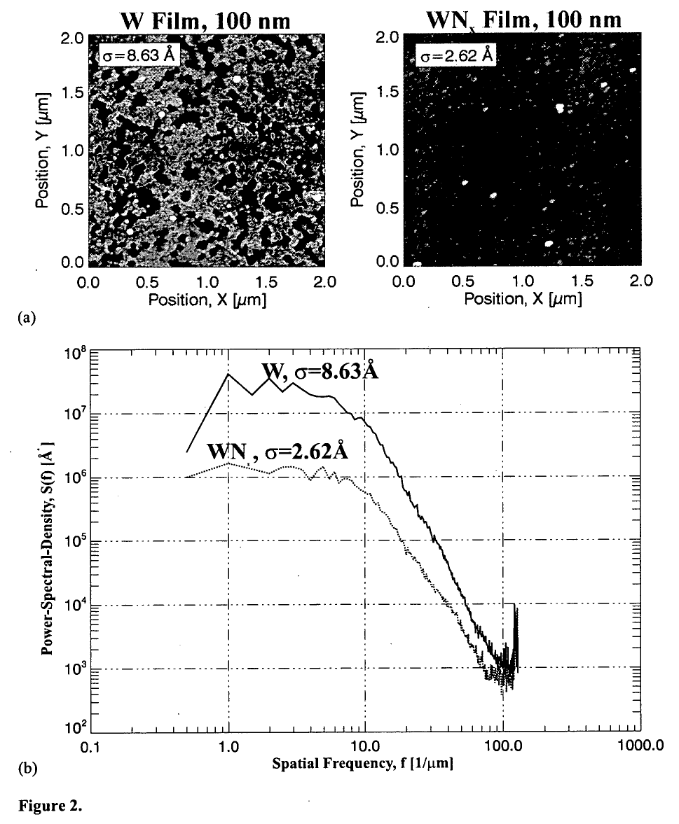

The AFM data also reveals a marked change in the surface topography of the W vs. WNₓ films. Shown in FIG. 2a are the AFM scans for a 100-nm-thick W film and a 100-nm-thick WNₓ film deposited in the Vactec system with an N₂ Gas Fraction of 9%; the corresponding PSD curves are shown in FIG. 2b. The W film has a relatively large rms surface roughness (σ=8.63 Å), and the surface topography reveals a large number of deep ‘holes’, roughly 0.1 μm in diameter. In contrast, the WNₓ film is much smoother (σ=2.62 Å), and shows nearly homogeneous topography. (The white ‘spots’ in these AFM images are caused by dust on the sample surface.) From FIG. 2b we see also that the reduction in surface roughness occurs over the entire range of spatial frequencies sampled. (Note that we find a steady increase in rms surface roughness with film thickness in these W films, which explains why the rms roughness values are so much higher than the values measured for the much thinner films presented in FIG. 1.)

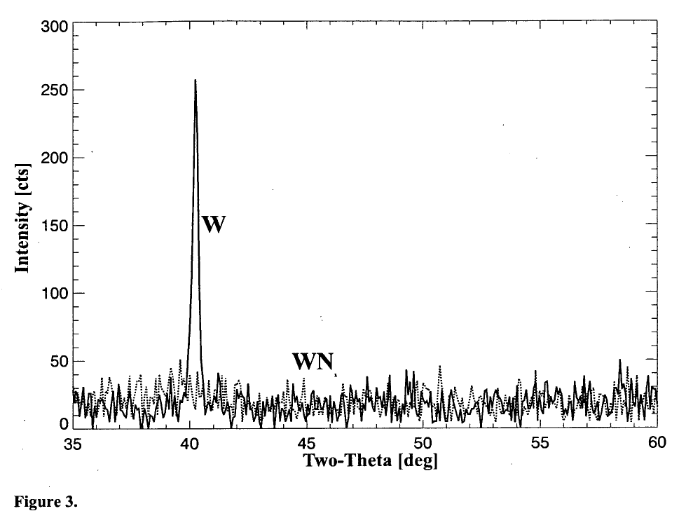

XRD measurements were made for the films shown in FIG. 2, and the results are shown in FIG. 3 where we plot X-ray intensity vs. 2θ from 35° to 60°. The strong peak near 2θ=40.5° in the W film is caused by diffraction from the bee W (110) lattice planes; this peak is completely absent in the data for the WNₓ film, suggesting an amorphous microstructure. The variation in surface topography in these films (FIG. 2) is presumably correlated with the polycrystalline vs. amorphous microstructure suggested by the XRD data.

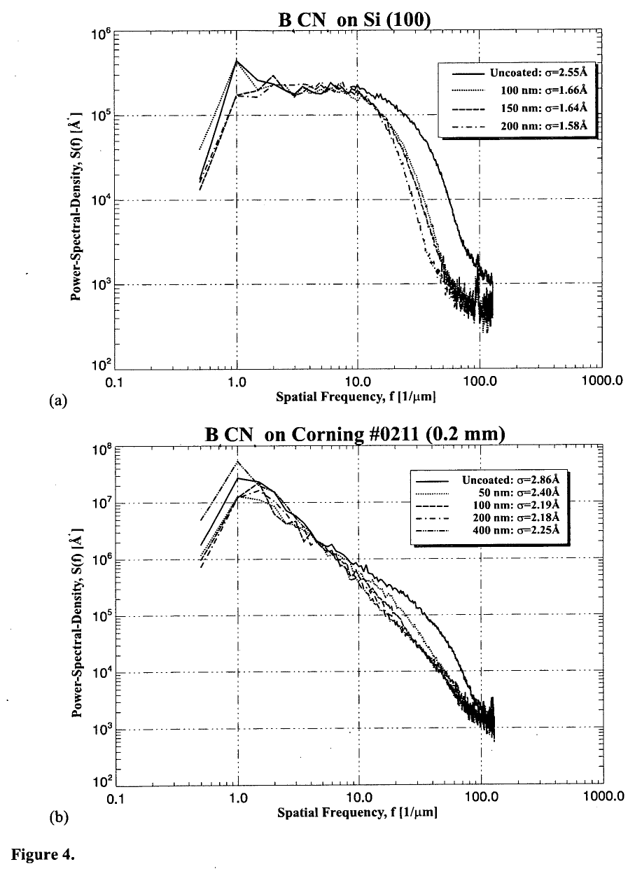

In another experiment, a series of B₄CNₓ films of varying thickness were deposited in the S-Gun system described above using an N₂ Gas Fraction of 6.4%. Films were deposited onto either Si (100) or 0.2-mm-thick glass (Corning #0211) substrates, and AFM measurements were made before and after film deposition. The resultant PSD curves are shown in FIG. 4. We find that the rms surface roughness of the B₄CNₓ films decreases with increasing film thickness (in contrast to the WNₓ films just discussed), and furthermore, the surface roughness is consistently less than the roughness of the underlying substrates in all cases; the PSD data shown in FIG. 4 indicate that these films thus act to reduce the very-high-spatial-frequency roughness of the underlying substrate, specifically for spatial frequencies greater than ˜10 μm⁻¹ (i.e., the spatial frequencies that matter most for optics designed for use at short X-ray wavelengths). For example, we find an rms surface roughness of approximately 2.5 Å for these uncoated Si (100) wafers, while the rms surface roughness of a 100-rim-thick B₄CNₓ film deposited onto such a substrate was found to be 1.66 Å. As another—and perhaps more important—example, we find an rms roughness of order 2.9 Å for the thin glass substrates studied here (which could be used to fabricate figured X-ray telescopes, for example as described in Koglin, Chen, Chonko et al., “Production and calibration of the first HEFT hard X-ray optics module, Proc. SPIE 5168, 100-111 (2004)), while the roughness after deposition of 100 nm of B₄CNₓ is 2.19 Å; again, from FIG. 4b it is clear that most of this reduction occurs at the highest spatial frequencies.

Based on the results shown in FIG. 4, these reactively-sputtered B₄CNₓ films can thus be used as ‘smoothing layers’, which can be deposited onto X-ray mirror substrates (prior to the deposition of a single-layer or multilayer X-ray reflective coating) in order to reduce the high-spatial-frequency roughness that has the potential to scatter short-wavelength X-rays out of the specular direction. The resultant reduction in substrate roughness will thus give rise to a significant increase in X-ray reflectance and a decrease in scattered X-ray intensity, crucial parameters in the construction of astronomical X-ray telescopes, for example. The relatively low stress obtained for these films (e.g., FIG. 1) reduces the potential for coating adhesion failures that might otherwise occur.

W/B₄C Multilayer Films

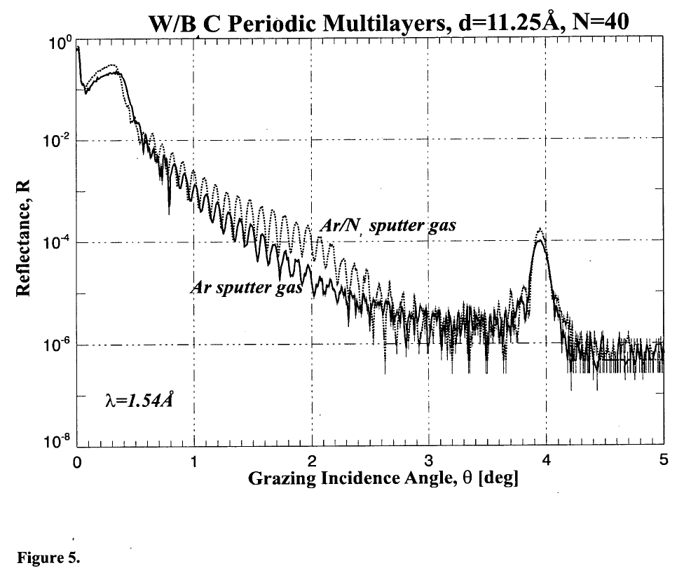

Driven by the encouraging results obtained for single-layer W and B₄C films described above, we have also investigated the performance of both periodic and depth-graded W/B₄C multilayer films deposited with and without nitrogen. Shown in FIG. 5 are the XRR data obtained for short-period W/B₄C multilayers containing N=40 bilayers, and having a period of d=11.25 Å. These films were both grown in the S-Gun system. For the film grown reactively, the N₂ Gas Fraction was once again set to 6.4%. The XRR results of FIG. 5 reveal that the reflected intensity at the first order Bragg peak near θ=3.9° is measurably higher for the film grown in the Ar/N₂ gas mixture relative to the film grown using only Ar gas, suggesting reduced interfacial roughness in the films grown reactively. Furthermore, the Kiessig fringes are also better defined in the case of the reactively-sputtered multilayer, also consistent with reduced interfacial and surface roughness. Fits to the XRR data suggest a small, but nevertheless significant reduction in interfacial roughness, from 4.7 Å to 4.4 Å.

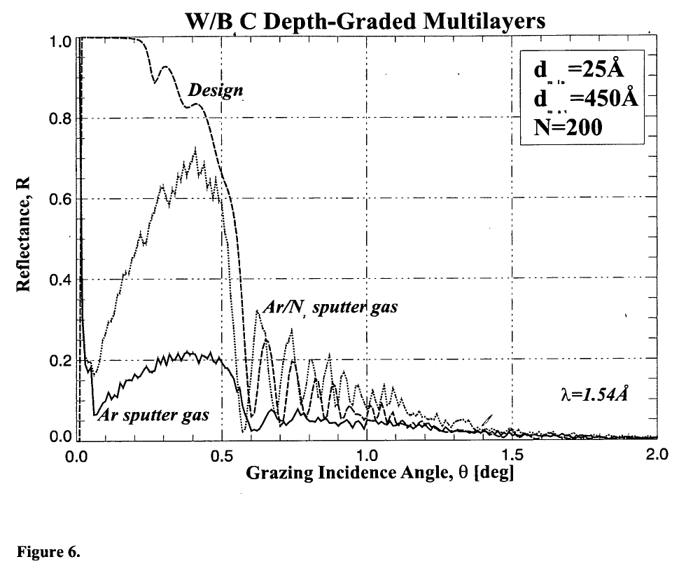

Shown in FIG. 6 are the XRR data for depth-graded WB₄C films deposited in the Vactec deposition system with and without nitrogen. These particular multilayers contain N=200 bilayers, with bilayer thicknesses in the range d=25-450 Å; this coating is designed for operation up to ˜12 keV at graze angles near θ˜0.3-0.4°, and thus would be suitable for use in an X-ray telescope such as the instrument currently proposed for NASA's future Constellation-X astronomy mission. The N₂ Gas Fraction was set to 9% for the reactively-sputtered multilayer. The XRR data shown in FIG. 6 are plotted on a linear scale, which better emphasizes the performance just above the critical angle in the range θ=0.5-1.0°, which is the angular range that is best correlated with the performance at the design X-ray energies. It is clear from FIG. 6 that the reactively-sputtered multilayer has performance that is much closer to the design curve (also shown), with well-defined interference fringes, while the film deposited without nitrogen has much lower reflectance overall and poorly-defined peaks. (Note that there are no ‘conventional’ Bragg peaks in these depth-graded multilayers designed for broad-energy response.) The XRR results are again consistent with reduced interfacial roughness in the reactively-sputtered film.

Wafer curvature measurements made on the same type of WB₄C depth-graded multilayers show a marked reduction in total film stress, from −1511 MPa for the non-reactively-sputtered as-deposited film, to a value of −421 MPa for the reactively-sputtered film. The large stress measured in the non-reactively-sputtered film is certainly sufficient to cause adhesion failures, and indeed the sample studied here, deposited onto a 3″ Si wafer, already began to craze at the edges after just a few hours upon removal from the coating chamber; no crazing has been observed to date in the reactively-sputtered coating.

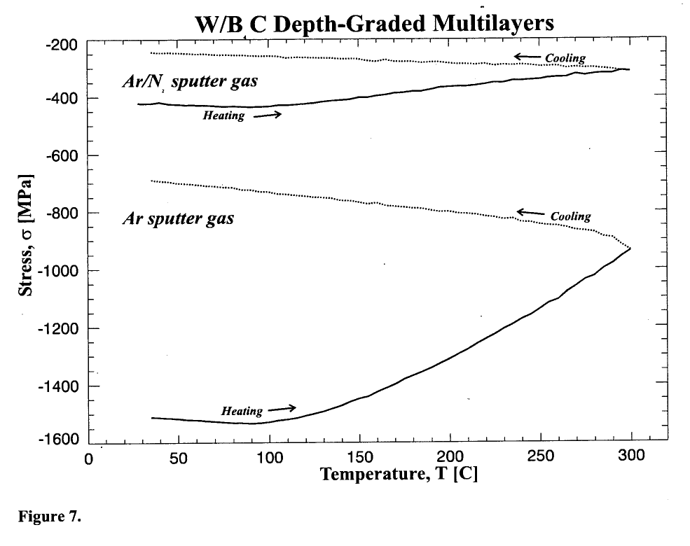

Finally, shown in FIG. 7 are stress-versus-temperature data obtained on these WB₄C depth-graded multilayers deposited reactively and non-reactively. Both films show irreversible stress changes at ˜90° C., with steady relaxation upon heating to 300° C. These changes in stress may be due to one or more possible mechanisms, including chemical reactions at the interfaces, viscous flow and/or densification within the individual layers, etc. In any case, the total change in stress (Δσ) after heating to 300° C. is significantly less in the case of the reactively sputtered film: Δσ=177 MPa for the reactively-sputtered film versus Δσ=822 MPa for the non-reactively sputtered film. (The linear cooling curves in both cases, as well as the linear portions of the heating curves from 25 to ˜90° C., correspond simply to thermal stresses resulting from the difference in thermal expansion coefficient between the film and the substrate.)

Co/C Multilayers

The inventive method has also been applied to create low-stress periodic and depth-graded Co/C multilayers showing superior X-ray performance. For the embodiments we investigated, we used an N₂ Gas Fraction of 6%. Using the S-Gun system, the power levels of the Co and C cathodes were 50 W and 60 W, respectively, the total sputter gas pressure was 2 mTorr, and the target-to-substrate distance was 8 cm. For Co/C films having a multilayer period of about 5 nm, the stress in films made using reactive sputtering was close to zero, while films made without reactive sputtering had stresses of about 400 MPa. Additionally, by using reactive sputtering, we are able to produce Co/C films with periods as small as 2 mm. By contrast, using non-reactive sputtering, we were unable to obtain periods smaller than ˜4 nm.

### INDUSTRIAL APPLICABILITY

Reactive sputtering using nitrogen in other applications has been widely used for many years, principally for the production of stoichiometric (or near-stoichiometric) nitrides for electronic, mechanical, and optical applications. Nanometer scaled superlattices and multilayers composed of transition metal nitrides have been widely studied as well, as such coatings can achieve significant increases in hardness, thereby finding a variety of useful mechanical applications. Reactive sputtering in nitrogen has also been recently used for the production of epitaxial CrN/ScN X-ray superlattices (see, e.g., Birch et al., “Single crystal CrN/ScN superlattice soft X-ray mirrors: Epitaxial growth, structure, and properties”, Thin Solid Films, 514, 10-19 (2006), the teachings of which are incorporated by reference herein). However, in that case the specific aim was to increase the thermal stability and wear resistance of these coatings relative to conventional Cr/Sc X-ray multilayers, in order to facilitate their use in harsh environments.

In contrast to the past utilization of reactive sputtering with nitrogen outlined above, the inventive method specifically reduces both stress and roughness simultaneously in W, B₄C, W/B₄C, and Co/C films (and likely in many other possible multilayer film combinations)—with little regard to chemical composition—in order to improve the X-ray performance of these coatings and to reduce the likelihood of stress-driven coating adhesion failures. Based on the experimental results presented above, we have demonstrated how these benefits have been realized in practice. We have also demonstrated reduced surface roughness (relative to the underlying substrate) in B₄CNₓ films, also grown by reactive sputtering in nitrogen using a stoichiometric B₄C sputter target; these B₄CNₓ films therefore can be used as smoothing layers in order to reduce the surface roughness of X-ray mirror substrates for spatial frequencies higher than ˜10 μm⁻¹, i.e., the range of spatial frequencies that will scatter hard X-rays into non-specular directions in many practical applications.

In summary, we have found that deposition of WNₓ and B₄CNₓ by reactive sputtering with nitrogen has a profound effect on the surface roughness and stress in these materials, presumably resulting from the corresponding changes in chemical composition and microstructure. These changes are manifest in multilayers containing WNₓ, B₄CNₓ, NiNₓ, CoNₓ, and CNₓ layers as well. In particular, the simultaneous reduction of film stress and roughness in both periodic and depth-graded W/B₄C and Co/C X-ray multilayers deposited reactively results in improved X-ray performance as well as improved coating adhesion.

The invention is not limited to the above description. For example, while argon has been used as the chief inert component of the sputter gas mixture in the above embodiments, other inert gases (e.g., He, Ne, Kr, Xe, etc.) may be employed. Furthermore, the invention can be applied to other sputtered film materials and multilayer material combinations, in order to simultaneously reduce stress and roughness just as has been demonstrated in the specific materials discussed here. Additionally, although exemplary embodiments were created using the Vactec and S-Gun systems, other known sputter deposition systems and techniques may be employed without departing from the invention. Moreover, although the invention has been described above in connection with X-ray reflective optical elements, it should be understood that the invention is also capable of being used in the formation of any type of X-ray optical elements, e.g., refractive elements, diffractive elements, and the like. All of these types of optical elements can benefit from the improved substrate smoothness afforded by the inventive substrate smoothing layer.

Having described certain embodiments of the invention, it should be understood that the invention is not limited to the above description or the attached exemplary drawings. Rather, the scope of the invention is defined by the claims appearing hereinbelow and any equivalents thereof as would be appreciated by one of ordinary skill in the art.

What is claimed is:

1. An X-ray reflective multilayer film produced by reactive sputter deposition using a sputter gas comprising nitrogen in combination with at least one inert gas.

2. An X-ray reflective multilayer film according to claim 1, wherein said nitrogen is incorporated into said film in a non-stoichiometric manner.

3. An X-ray reflective multilayer film according to claim 1, wherein a gas fraction of said nitrogen is between approximately 5% and approximately 25%.

4. An X-ray reflective multilayer film according to claim 1, wherein said inert gas comprises argon.

5. An X-ray reflective multilayer film according to claim 1, wherein the materials to be reactively sputtered comprise tungsten and boron carbide in alternating layers of said multilayer film.

6. An X-ray reflective multilayer film according to claim 1, wherein the materials to be reactively sputtered comprise nickel and boron carbide in alternating layers of said multilayer film.

7. An X-ray reflective multilayer film according to claim 1, wherein the materials to be reactively sputtered comprise cobalt and carbon in alternating layers of said multilayer film.

8. An X-ray optical element substrate smoothing layer, said smoothing layer produced by reactive sputter deposition using a sputter gas comprising nitrogen in combination with at least one inert gas,
wherein deposition of said smoothing layer onto said substrate reduces a surface roughness of said substrate.

9. An X-ray optical element substrate smoothing layer according to claim 8, wherein a gas fraction of said nitrogen is between approximately 5% and approximately 25%.

10. An X-ray optical element substrate smoothing layer according to claim 8, wherein said inert gas comprises argon.

11. An X-ray optical element substrate smoothing layer according to claim 8, wherein the material to be reactively sputtered comprises boron carbide.

12. A method of creating extremely smooth and low-stress X-ray reflective films, comprising the steps of:
providing a film substrate; and
sputtering at least one material onto the substrate using a sputter gas mixture of nitrogen and at least one inert gas.

13. A method according to claim 12, wherein a gas fraction of said nitrogen is between approximately 5% and approximately 25%.

14. A method according to claim 12, wherein said inert gas comprises argon.

15. A method according to claim 12, said sputtering step further comprising the steps of depositing two different materials in alternating layers to form an X-ray multilayer film.

16. A method according to claim 15 wherein the two different materials of said depositing step comprise at least one of the following pairs: i) tungsten and boron carbide; ii) nickel and boron carbide; or iii) cobalt and carbon.

17. A method of creating an X-ray optical element substrate smoothing layer, comprising the steps of:
providing an optical element substrate; and
reducing a surface roughness of the substrate by sputtering a material onto the substrate using a sputter gas mixture of nitrogen and at least one inert gas.

18. A method according to claim 17, further comprising the step of depositing at least one additional layer of material atop the smoothing layer to form an X-ray reflective film.

19. A method according to claim 17, wherein the sputter material includes boron carbide.
